(19) United States
(12) Patent Application Publication
(10) Pub. No.: US 2012/0122316 A1
(43) Pub. Date: May 17, 2012

(54) METHOD FOR SURFACE TREATMENT OF A WAFER

(76) Inventors: Motoi Kurokami, Tokyo (JP); Shigeru Okuuchi, Tokyo (JP); Hiroaki Sato, Tokyo (JP)

(21) Appl. No.: 13/384,889

(22) PCT Filed: Jul. 27, 2010
(86) PCT No.: PCT/JP2010/004775

§ 371 Date: Jan. 19, 2012

(30) Foreign Application Priority Data
Jul. 28, 2009 (JP) 2009-175226

(51) Int. Cl. H01L 21/306

(52) U.S. Cl. 438/704; 257/E21.229

(57) ABSTRACT

An object of the present invention is to provided a wafer exhibiting excellent surface properties, in which variation in reaction, which has been concerned in surface treatment with a diffusion controlled process such as conventional wet treatment, is effectively suppressed in a method for surface treatment of a wafer involving a chemical treatment.

Provided is a method for surface treatment of a wafer involving a chemical treatment, the chemical treatment including a reaction controlled process, and a diffusion controlled process following the reaction controlled process.

### TECHNICAL FIELD

The present invention relates to a method for surface treatment of a wafer, in particular, of a silicon wafer, and also to a method for cleaning a surface of a wafer, in particular, of a silicon wafer.

### RELATED ART

Wafers including silicon wafers used as semiconductor substrates are formed into products through various surface treatment steps with chemical reaction. For example, a wafer after rough polishing is subjected to an etching process to remove damages occurring on the wafer surface due to machine works. The wafer after final polishing is subjected to cleaning and etching processes to remove contaminants attached on the wafer surface and give a desired flatness to the wafer surface.

The surface treatment steps are generally performed through wet treatment. For example, in an etching process after polishing, wet etching using, for example, HF and HNO₃ is performed. In the cleaning and etching processes after final polishing, RCA cleaning using SC1 cleaning and SC2 cleaning is performed. Further, in the cleaning and etching processes after the final polishing, a method of performing the etching by dipping the wafer into ozone water and a solution containing hydrofluoric acid after the SC1 cleaning is employed in place of the RCA cleaning (Patent Document 1).

### RELATED ART DOCUMENT

### Patent Document

Patent Document 1: Japanese Patent Application Laid-open No. 2000-049133

The most important point in the surface treatment steps is to apply the surface treatment uniformly on the entire wafer surface, in other words, to suppress variation in reaction. For example, in the case where the variation in reaction occurs in the etching process after rough polishing, unevenness occurs on the wafer surface, whereby the desired flatness cannot be obtained on the wafer surface even if the final polishing is applied thereafter. Further, in the case where the variation in reaction occurs in the cleaning and etching processes after the final polishing, the unevenness occurs on the wafer surface, and the number of light point defects (LPD) increases, whereby the quality of the wafer surface deteriorates.

However, the surface treatment steps through a diffusion controlled process such as the wet treatment are likely to cause the variation in reaction. In particular, it has been concerned that quality of the wafer surface deteriorates due to the increase in the number of LPDs, which can be seen in the wafer after the final polishing. Currently, any effective solving means against the concern above has not been proposed. With the increase in the demand for improving the quality of the wafer surface properties, there is an urgent need to find the effective solving means against the concern above.

### DISCLOSURE OF THE INVENTION

### Problems for Solving the Problem

The present invention has been made in view of the circumstances described above, and an object of the present invention is to provide a wafer exhibiting excellent surface properties, in which variation in reaction, which has been concerned in the surface treatment steps with conventional wet treatment, is effectively suppressed in the method for treatment the wafer surface involving a chemical treatment.

### Means for Solving the Problem

The present inventors made a keen study to solve the problems described above, and as a result, found the following (a) to (c).

(a) In the method for treatment of the wafer surface involving the chemical reaction through the diffusion controlled process, the variation in reaction is caused mainly by nonuniformity of the properties of the wafer surface resulting from foreign substances and the like attached on the wafer surface.

(b) Providing a step for making properties of the wafer surface uniform prior to the diffusion controlled process is effective in suppressing the variation in reaction.

(c) Providing a predetermined reaction controlled process before the diffusion controlled process is effective in making the properties of the wafer surface uniform.

The present invention has been made on the basis of the findings described above, and main points thereof are as follows:

(1) A method for surface treatment of a wafer involving a chemical treatment, characterized in that the chemical treatment includes a reaction controlled process, and a diffusion controlled process following the reaction controlled process.

(2) The method for surface treatment of a wafer according to (1) above, in which the reaction controlled process includes a step of treatment of a surface using a single surface treatment agent and/or a step of surface treatment using plural surface treatment agents.

(3) The method for surface treatment of a wafer according to (1) or (2) above, in which the reaction controlled process is a vapor-phase reaction process.

(4) The method for surface treatment of a wafer according to (3) above, in which the vapor-phase reaction process is an oxidation process.

(5) The method for surface treatment of a wafer according to (3) above, in which the vapor-phase reaction process is a reduction process.

(6) The method for surface treatment of a wafer according to (3) above, in which the vapor-phase reaction process is an oxidation process and a reduction process following the oxidation process.

(7) The method for surface treatment of a wafer according to any one of (1) to (6) above, in which the diffusion controlled process is a liquid-phase reaction process.

(8) A method for cleaning a surface of a silicon wafer, wherein the method for surface treatment of a wafer according to any one of (1) to (7) above is employed.

### Effect of the Invention

According to the present invention, it is possible to provide a wafer exhibiting excellent surface properties, in which variation in reaction, which has been concerned in the surface treatment with the diffusion controlled process such as conventional wet treatment, is effectively suppressed in the method for surface treatment of a wafer involving a chemical treatment.

### BRIEF DESCRIPTION OF THE DRAWINGS

FIG. 1 is a diagram illustrating a manner in which a chemical treatment agent diffuses at the time of surface treatment of a wafer with a chemical treatment.

FIG. 2 is a diagram illustrating a state of the wafer surface after the SC1 cleaning.

FIG. 3 is a diagram schematically illustrating a main portion of a treating device with a single-wafer type used for the surface treatment of a wafer according to the present invention.

FIG. 4 is a diagram illustrating properties of a wafer surface of Example 1.

FIG. 5 is a diagram illustrating properties of a wafer surface of Comparative Example 1.

FIG. 6 is a diagram illustrating properties of a wafer surface of Example 2.

FIG. 7 is a diagram illustrating properties of a wafer surface of Example 3.

### BEST MODE FOR CARRYING OUT THE INVENTION

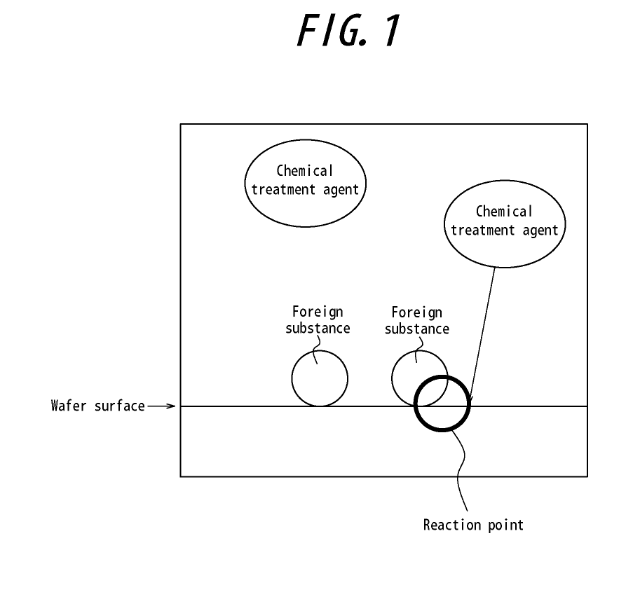

A method for surface treatment of a wafer according to the present invention provides a method for surface treatment of a wafer involving a chemical treatment including a reaction controlled process, and a diffusion controlled process following the reaction controlled process. Note that, in the present invention, judgment between a diffusion control and a reaction control is made with reference to a wafer surface (see FIG. 1). More specifically, the diffusion controlled process refers to a case where the time required for a chemical treatment agent to reach the entire area of the wafer surface is longer than the time required for chemical reaction on the wafer surface. On the other hand, the reaction controlled process refers to a case where the time required for the chemical treatment agent to reach the entire area of the wafer surface is shorter than the time required for chemical reaction on the wafer surface. Hereinbelow, the present invention will be described in detail on the basis of cleaning and etching processes after final polishing, which is an example of the method for treatment of a silicon wafer surface involving the chemical treatment.

On the surface of the silicon wafer after the final polishing, there are attached fine particles, organic substances and metal impurities, and machining damages are formed due to the final polishing. Therefore, it is necessary to clean the surface of the silicon wafer after the final polishing, and remove the machining damages. As the method for cleaning and removal thereof, there is known a method for applying an etching process in which the surface of the silicon wafer is dipped into the ozone water and the hydrofluoric acid after the SC1 cleaning, as described above (Patent Document 1).

In the method described above, the silicon wafer is first dipped into the SC1 cleaning solution (liquid mixture of hydrogen peroxide and ammonium hydroxide) to oxidize the surface of the silicon wafer with the hydrogen peroxide. At this time, the fine particles and organic substances attached on the surface of the silicon wafer are removed from the surface of the wafer with the etching function of the ammonium hydroxide, and then, the machining damages are removed from the surface of the silicon wafer.

Then, the silicon wafer is dipped into the ozone water to oxidize the surface of the silicon wafer. Next, the silicon wafer is dipped into the solution containing hydrofluoric acid to remove a natural oxide film formed on the surface of the silicon wafer. At this time, the fine particles and the metal impurities on the natural oxide film and the metal impurities contained in the natural oxide film are removed together with the natural oxide film, whereby the surface of the silicon wafer is cleaned. Further, by dipping the silicon wafer again into the ozone water after the process involving hydrofluoric acid, a silicon oxide film is formed on the surface of the silicon wafer, whereby it is possible to avoid the fine particles in the air attaching on the silicon wafer after the silicon wafer is taken out from the ozone water after dipping. Note that the reason for dipping the silicon wafer into the ozone water to apply the oxidation process to the surface of the silicon wafer before the silicon wafer is dipped into the solution containing the hydrofluoric acid is that, after the oxidation process, the fine particles can be easily detached from the surface of the silicon wafer at the time of process involving hydrofluoric acid thereafter.

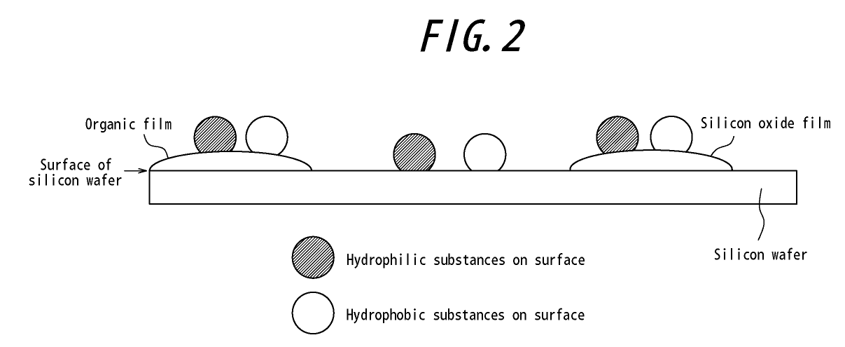

Next, description will be made of a step after the SC1 cleaning, that is, of cleaning and etching processes after the removal of the fine particles, organic substances and machining damages on the surface of the silicon wafer. As illustrated in FIG. 2, the silicon wafer after the SC1 cleaning has a surface, for example, in which hydrophilic surface-substances (for example, fine particles) and hydrophobic surface-substances (for example, metal impurities) (i) are attached indirectly on the wafer surface through an organic film, (ii) are attached directly on the wafer surface, and (iii) are attached indirectly on the wafer surface through the silicon oxide film, and (iv) has a surface without having any substances and any films on the surface described above. In the case where the silicon wafer having the nonuniform surface as described above is dipped into the ozone water and solution containing hydrofluoric acid, it is expected that the following phenomena occur.

A process of ozone water in which the silicon wafer is dipped into the ozone water and a process of hydrofluoric acid in which the silicon wafer is dipped into the solution containing the hydrofluoric acid are a diffusion controlled process. The time required for the ozone and the hydrogen fluoride in the solution to reach the surface of the silicon wafer differs according to the states (i) to (iv) of the surface of the silicon wafer described above. The time required for the ozone and the hydrogen fluoride in the solution to reach the surface of the silicon wafer is the shortest in the state (iv) in which there exist no substances preventing the ozone and the hydrogen fluoride from diffusing on the wafer surface. Further, it is considered that the time required for the ozone and the hydrogen fluoride in the solution to reach the surface of the silicon wafer differs according to the states (i) to (iii). Therefore, before the ozone and the hydrogen fluoride in the solution reach the surface of the silicon wafer having the states (i) to (iii) described above, chemical reaction proceeds earlier in a portion of the silicon wafer surface having the state (iv) described above, where the ozone and the hydrogen fluoride in the solution have already arrived. It is considered that this causes the variation in reaction. Further, since the time required for the ozone and the hydrogen fluoride in the solution to reach the surface of the silicon wafer differs according to the states (i) to (iii), the degree of progress of the chemical reaction in the surfaces of the silicon wafer having the states (i) to (iii) described above differs, which causes the variation in reaction.

More specifically, in the process of ozone water, the ozone in the solution directly reaches the surface of the silicon wafer in the state (iv) described above to oxidize the silicon wafer. On the other hand, in the states (i) to (iii) described above, it takes longer time to oxidize the silicon wafer due to existence of the substances and films described above. As a result, when the silicon wafer after the process of ozone water is observed in terms of thickness of the silicon oxide film formed from the wafer surface toward the center of the thickness of the wafer (depth direction), it is confirmed that the thickness of the silicon oxide film of the (iv) described above is thicker, and oxidization reaches a position deeper in the silicon wafer as compared with the (i) to (iii) described above. Further, among the (i) to (iii) described above, there occurs variation in thickness of the silicon oxide film.

In the process of hydrofluoric acid following the process of ozone water, the silicon oxide film formed on the silicon wafer is etched and removed. However, the thickness of the silicon oxide film formed from the surface of the silicon wafer toward the center of the thickness of the wafer (depth direction) is not uniform as described above. The hydrofluoric acid has an etching function against the silicon oxide film, while it has almost no etching function against the silicon. Therefore, the silicon wafer after the process of hydrofluoric acid, in which the silicon oxide film is removed, has an unevenly formed surface due to the nonuniformity in thickness of the silicon oxide film, and the number of LPD increases, whereby a wafer surface having a desired quality cannot be obtained.

To solve the problems described above, in the present invention, a process of ozone gas (oxidation process) and/or a process of hydrogen fluoride gas (reduction process), which are the reaction controlled processes, are applied prior to the process of ozone water to make properties of the surface of the silicon wafer uniform. As described in (i) to (iv) above, the surface of the silicon wafer after the SC1 cleaning is in the nonuniform state. In the case of the process of ozone gas, which involves the vapor-phase reaction, diffusion speed of the ozone in the vapor phase is significantly higher as compared with the ozone in the liquid phase. Therefore, at the time when the silicon wafer is subjected to the process of ozone gas, the ozone in the vapor phase reaches each portion of the (i) to (iv) on the surface of the silicon wafer at almost the same time. Therefore, in the silicon wafer after the process of ozone gas, the thickness of the silicon oxide film formed from the surface of the silicon wafer toward the center of the thickness of the wafer (depth direction) is almost uniform throughout the surface of the silicon wafer, and the nonuniformity of the wafer surface can be alleviated.

Further, through the process of hydrogen fluoride gas, the silicon oxide film formed on the silicon wafer is etched and removed. Unlike the silicon wafer after the process of ozone water, the thickness of the silicon oxide film formed from the surface of the silicon wafer toward the center of the thickness of the wafer (depth direction) is almost uniform in the silicon wafer after the process of ozone gas. Therefore, the silicon wafer after the process of hydrogen fluoride gas, from which the silicon oxide film is removed, has a surface almost uniform.

Through the reaction controlled process (process of ozone gas and/or process of hydrogen fluoride gas) described above, substances and film attached on the surface of the silicon wafer are removed to some degree. However, in the process of ozone gas and the process of hydrogen fluoride gas, which are the vapor-phase processes, reaction is rate controlled. Therefore, those processes are less effective in removing the fine particles and the like as compared with the process of ozone water and the process of hydrofluoric acid, which are processes under the liquid phase, and there is a possibility that the foreign substances such as fine particles are not completely removed from the surface of the silicon wafer after the process of hydrogen fluoride gas described above. In view of the facts described above, in the present invention, the fine particles and the like are completely removed from the surface of the silicon wafer by applying the conventional process of ozone water or process of hydrofluoric acid, which are diffusion controlled processes, after applying the reaction controlled process (process of ozone gas and/or process of hydrogen fluoride gas).

Different from the conventional method in which only the process of ozone water and the process of hydrofluoric acid, which are diffusion controlled processes, are applied, in the present invention, the reaction controlled process (process of ozone gas and/or process of hydrogen fluoride gas) is applied prior to the diffusion controlled process, to alleviate the nonuniformity of the surface of the silicon wafer. Therefore, the variation in reaction can be effectively suppressed in the process of ozone water and the process of hydrofluoric acid, which are the following diffusion controlled processes. This makes it possible to manufacture a silicon wafer having the even surface and reduced number of LPDs, and exhibiting excellent quality of wafer surface.

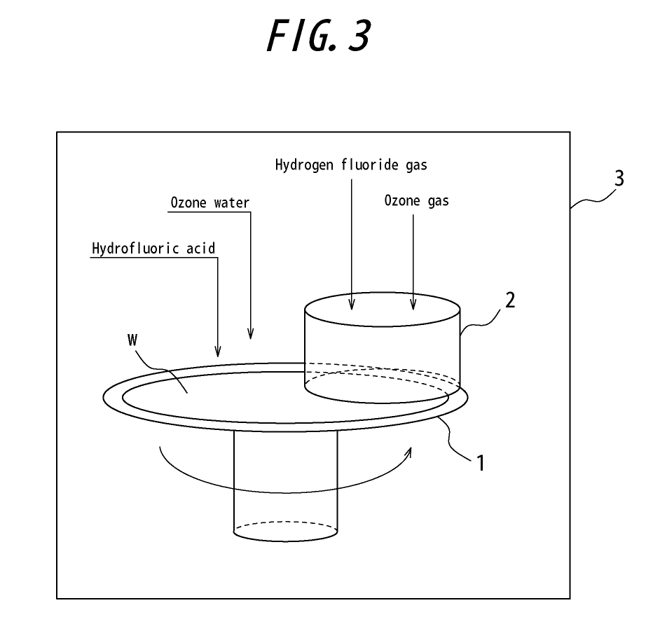

For performing the wafer-surface treatment according to the present invention, it may be possible to employ various treating types such as a batch type and a single-wafer type. However, it is preferable to employ the single-wafer type for the reasons of improvement in treating efficiency, improvement of efficiency in replacement of chemical solution for the wafer surface, and the like. FIG. 3 is a diagram schematically illustrating a main portion of a treating device with the single-wafer type used for the surface treatment of a wafer according to the present invention. As illustrated in FIG. 3, the treating device has a chamber 3, a rotary table 1 for rotating a wafer w in a state where the wafer w to be processed is fixed, and a gas supplying cup 2 having an opening portion at a lower portion thereof for supplying an ozone gas or hydrogen fluoride gas from a not-shown gas supplying nozzle onto a wafer surface. At the time of applying the process of ozone gas or the process of hydrogen fluoride gas, the ozone gas or hydrogen fluoride gas is supplied from the not-shown gas supplying nozzle through the gas supplying cup 2 onto the wafer surface while the rotary table 1 is being rotated, for example, at a revolution number in the range of 10 rpm to 500 rpm. The supplied ozone gas or hydrogen fluoride gas passes through a not-shown exhaust pipe provided at the side of the chamber 3, and is discharged to the outside of the chamber 3 by means of a not-shown exhaust system. At the time of applying the process of ozone water or the process of hydrofluoric acid, the ozone water or the solution containing hydrogen fluoride gas is supplied from a not-shown supplying nozzle onto the wafer surface while the rotary table 1 is being rotated, for example, at a revolution number in the range of 10 rpm to 500 rpm.

It is preferable that the concentration of the ozone gas supplied at the time of the process of ozone gas is in the range of 10 ppm to 100 ppm (1×10⁻³ to 1×10⁻² mass %). This is because, in the case where the concentration of the ozone gas is less than 10 ppm, oxidation reaction of the surface of the silicon wafer does not sufficiently proceed. On the other hand, in the case where the concentration exceeds 100 ppm, there is a possibility that components constituting the treating device corrode. Note that, in the present invention, the concentration of the ozone gas and the concentration of the hydrogen fluoride gas, which will be described later, are indicated in percent by mass. Further, it is preferable that the time for the process of ozone gas is in the range of 10 sec to 600 sec. This is because, in the case where the time for the process of ozone gas is less than 10 sec, the oxidation reaction of the silicon wafer does not sufficiently proceed. On the other hand, in the case where the time for the process of ozone gas is 10 sec or more, the oxidation reaction proceeds as the time for the process increases, and the silicon oxide film having a predetermined thickness is formed on the wafer surface. Further, in the case where the time for the process exceeds 600 sec, the reaction reaches an equilibrium state, and the oxidation reaction does not proceed any more. Depending on application, the flow rate of the ozone gas is set, for example, in accordance with size of the wafer and the exhausting capacity of the exhaust system for discharging the gas in the chamber. The temperature of the process of ozone gas is preferably in the range of 10° C. to 30° C. This is because, in the case where the temperature of the process of ozone gas is less than 10° C., moisture in the chamber condenses and condensation occurs, which attaches to the silicon wafer, whereby there occurs variation in thickness of the silicon oxide film formed through the process of ozone gas. On the other hand, in the case where the temperature of the process exceeds 30° C., the ozone gas is activated, possibly causing corrosion in the components constituting the treating device.

It is preferable that, in the case where the process of hydrogen fluoride gas is performed sequentially after the process of ozone gas, the concentration of the hydrogen fluoride gas supplied at the time of the process of hydrogen fluoride gas is in the range of 10 ppm to 10000 ppm (1×10⁻³ to 1 mass %). This is because, in the case where the concentration of the hydrogen fluoride gas is less than 10 ppm, the reduction reaction does not sufficiently proceed, and hence, the silicon oxide film formed on the wafer surface cannot be removed. On the other hand, in the case where the concentration of the hydrogen fluoride gas exceeds 10000 ppm, there is a possibility that the components constituting the treating device corrode. Further, the time for the process of hydrogen fluoride is preferably in the range of 5 sec to 600 sec. This is because, in the case where the time for the process of hydrogen fluoride is less than 5 sec, the reduction reaction does not sufficiently proceed, and hence, the silicon oxide film formed on the wafer surface cannot be removed. Further, in the case where the time for the process of hydrogen fluoride is 5 sec or more, the reduction reaction proceeds as the time for the process increases, and the silicon oxide film formed on the wafer surface is removed. In the case where the time for the process exceeds 600 sec, the reaction reaches an equilibrium state, and the reduction reaction does not proceed any more. Depending on application, the flow rate of the hydrogen fluoride gas is set, for example, in accordance with size of the wafer and the exhausting capacity of the exhaust system for discharging the gas in the chamber. The temperature of the process of hydrogen fluoride gas is preferably in the range of 10° C. to 40° C. This is because, in the case where the temperature of the process of hydrogen fluoride gas is less than 10° C., moisture in the chamber condenses and condensation occurs, which attaches to the silicon wafer, whereby the silicon oxide film formed on the wafer surface cannot be removed in a uniform manner. On the other hand, in the case where the temperature of the process exceeds 40° C., the hydrogen fluoride gas is activated, possibly causing corrosion in the components constituting the treating device.

After completion of the process of hydrogen fluoride gas, the process of ozone water and the process of hydrofluoric acid are performed by removing the gas supplying cup 2, and supplying treatment solutions onto the surface of the wafer w in the order of the ozone water, the hydrofluoric acid solution and the ozone water.

Note that the concentration of the ozone water supplied at the time of the process of ozone water is preferably in the range of 0.5 ppm to 20 ppm (5×10⁻⁵ to 2×10⁻³ mass %). This is because, in the case where the concentration of the ozone water is less than 0.5 ppm, it is difficult to form the uniform silicon oxide film on the wafer surface. In the case where the concentration of the ozone water is 0.5 ppm or more, the oxidation reaction proceeds as the concentration of the ozone water increases, and the silicon oxide film having a predetermined thickness is formed on the wafer surface. Further, in the case where the concentration exceeds 20 ppm, the reaction reaches an equilibrium state, and the oxidation reaction does not proceed any more. Note that, in the present invention, the concentration of the ozone water and the hydrofluoric acid, which will be described later, are indicated in percent by mass. Further, the time for the process of ozone water is preferably in the range of 5 sec to 120 sec. This is because, in the case where the time for the process of ozone water is less than 5 sec, it is difficult to form the uniform silicon oxide film on the wafer surface. In the case where the time for the process of ozone water is 5 sec or more, the oxidation reaction proceeds as the time for the process increases, and the silicon oxide film having a predetermined thickness is formed on the wafer surface. Further, in the case where the time exceeds 120 sec, the reaction reaches an equilibrium state, and the oxidation reaction does not proceed any more. Depending on application, the flow rate of the ozone water is set in accordance with size of the wafer and the number of revolution of the wafer. The temperature of the process of ozone water is preferably in the range of 10° C. to 30° C. This is because, in the case where the temperature of the process of ozone water is less than 10° C., the efficiency of dissolution of ozone decreases, and it is difficult to maintain the concentration of the ozone at a constant value. On the other hand, in the case where the temperature of the process exceeds 30° C., the ozone is self-resolved, and hence, it is difficult to maintain the concentration of the ozone water at a constant value on the wafer surface.

The concentration of the hydrofluoric acid supplied at the time of the process of hydrofluoric acid is preferably in the range of 0.01% to 5% (0.01 to 5 mass %).

This is because, in the case where the concentration of the hydrofluoric acid is less than 0.01%, the reduction reaction does not sufficiently proceed, and hence, the silicon oxide film formed on the wafer surface cannot be removed. In the case where the concentration of the hydrofluoric acid is 0.01% or more, the reduction reaction proceeds as the concentration of the hydrofluoric acid increases, whereby the silicon oxide film formed on the wafer surface can be removed. In the case where the concentration exceeds 5%, the reaction reaches an equilibrium state, and the reduction reaction does not proceed any more. The time for the process of hydrofluoric acid is preferably in the range of 1 sec to 120 sec. This is because, in the case where the time for the process of hydrofluoric acid is less than 1 sec, the reduction reaction does not sufficiently advance, and hence, the silicon oxide film formed on the wafer surface cannot be removed. In the case where the time for the process of hydrofluoric acid is 1 sec or more, the reduction reaction proceeds as the time of the process increases, and hence, the silicon oxide film formed on the wafer surface can be removed. In the case where the time of the process exceeds 120 sec, the reaction reaches an equilibrium state, and the reduction reaction does not proceed any more. Depending on application, the flow rate of the hydrofluoric acid is set in accordance with size of the wafer and the number of revolution of the wafer. The temperature of the process of hydrofluoric acid is preferably in the range of 10° C. to 40° C. This is because, in the case where the temperature of the process of hydrofluoric acid is less than 10° C., the reduction reaction does not sufficiently proceed, and, hence, the silicon oxide film formed on the wafer surface cannot be removed. On the other hand, in the case where the temperature of the process exceeds 40° C., the hydrogen fluoride gas is discharged from the hydrofluoric acid solution through evaporation, and hence, it is difficult to maintain the concentration of the hydrofluoric acid solution to be constant.

It should be noted that, in the description above, the silicon wafer is subjected to the oxidation process through the process of ozone gas. However, in the present invention, it may be possible to employ the vapor-phase reaction process using, for example, an oxygen gas or chlorine gas, in place of the ozone gas. Further, in the description above, the silicon wafer is subjected to the reduction process through the process of hydrogen fluoride gas. However, in the present invention, it may be possible to employ the vapor-phase reaction process using a hydrogen gas, in place of the hydrogen fluoride gas.

Further, in the description above, the oxidation process (process of ozone gas) is performed by using a single surface treatment agent, and the reduction process (process of hydrogen fluoride gas) is performed by using a single surface treatment agent. However, it may be possible to perform the oxidation process and the reduction process by using a mixture of plural surface treatment agents. For example, in place of the process of ozone gas, it may be possible to apply the oxidation process to the silicon wafer by using a mixture gas formed by gases optionally selected from an ozone gas, oxygen gas, chlorine gas and inert gas such as an Ar. Alternatively, in place of the process of hydrogen fluoride gas, it may be possible to perform the etching process (reduction process) by using a mixture gas formed by gases optionally selected from a hydrogen fluoride gas, hydrogen gas, and inert gas such as an Ar.

As described above, according to the present invention, it is possible to provide a wafer exhibiting excellent surface properties, in which variation in reaction, which has been concerned in the surface treatment with the diffusion controlled process such as conventional wet cleaning processing, is effectively suppressed in the method for treating the wafer surface involving chemical treatment. Note that description has been made of the present invention by giving an example of the processes after the SC1 cleaning. However, the present invention is not limited to this, and it may be possible to apply the present invention to various methods for treating the wafer surface, such as a method in which the wafer surface is processed prior to the etching process applied to the wafer surface by using an acid-based etching solution or an alkaline etching solution.

Further, in the description above, the wet treatment and the dry treatment have been explained as the diffusion controlled process and the reaction controlled process, respectively. However, the present invention is not limited to these. The most significant feature of the present invention is in that the nonuniformity of the wafer surface state is alleviated by providing the reaction controlled process prior to the diffusion controlled process. Therefore, any of the wet treatment and the dry treatment is possible in the reaction controlled process, provided that the nonuniformity of the wafer surface state can be alleviated.

### EXAMPLE

Next, effects of the present invention will be described through Examples of the present invention and Comparative Example. However, Examples of the present invention are merely examples for explaining the present invention, and do not limit the present invention.

### Example 1

The following processes of (1) to (5) were sequentially applied to a silicon wafer having a diameter of 300 mm and subjected to the SC1 cleaning by using the treating device illustrated in FIG. 3. The number of revolution of the wafer was set to 50 rpm.

(1) Process of Ozone Gas

(concentration of gas: 200 ppm, flow rate of gas: 5 L/min, time for process: 60 sec, temperature of process: 20° C.)

(2) Process of Hydrogen Fluoride Gas

(concentration of gas: 5000 ppm, flow rate of gas: 5 L/min, time for process: 60 sec, temperature of process: 20° C.)

(3) Process of Ozone Water

(concentration of ozone water: 10 ppm, flow rate: 5 L/min, time for process: 60 sec, temperature of process: 20° C.)

(4) Process of Hydrofluoric Acid

(concentration of hydrofluoric acid: 1%, flow rate: 5 L/min, time for process: 60 sec, temperature of process: 20° C.)

(5) Process of Ozone Water

(concentration of ozone water: 10 ppm, flow rate: 5 L/min, time for process: 60 sec, temperature of process: 20° C.)

### Comparative Example 1

The processes of (3) to (5) above were sequentially applied to a silicon wafer having a diameter of 300 mm and subjected to the SC1 cleaning under conditions similar to Example 1.

### Example 2

The processes of (1) and (3) to (5) above were sequentially applied to a silicon wafer having a diameter of 300 mm and subjected to the SC1 cleaning under conditions similar to Example 1.

### Example 3

The processes of (2) to (5) above were sequentially applied to a silicon wafer having a diameter of 300 mm and subjected to the SC1 cleaning under conditions similar to Example 1.

[Measurement of the Number of LPD]

For the silicon wafers of Examples 1 to 3 and Comparative Example 1, measurement was made on properties of wafer surfaces through the following method. More specifically, for the silicon wafers before and after the surface treatment, the number of LPD having a size of 0.08 μm or lower and existing on the wafer surface was counted by using a particle counter SurfScanSP2 made by KLA-Tencor Corporation.

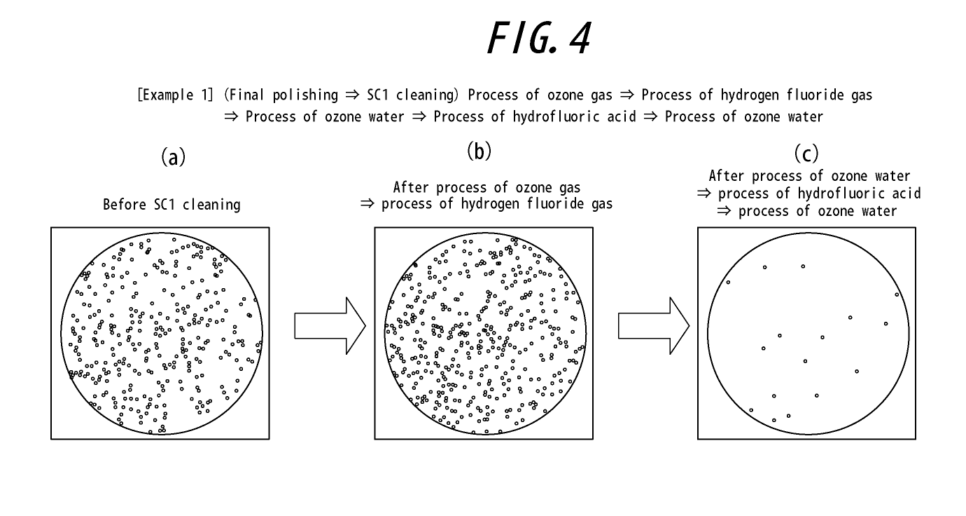

The measurement results are shown in FIGS. 4 to 7 as maps indicating distribution of and the number of the LPD having a size of 0.08 μm or lower and existing on the wafer surface.

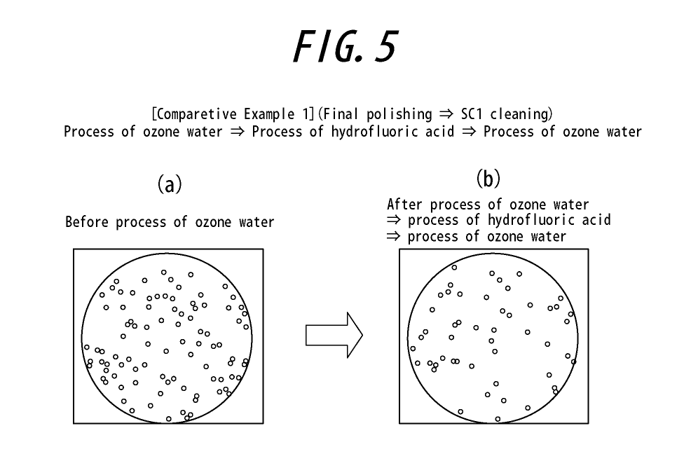

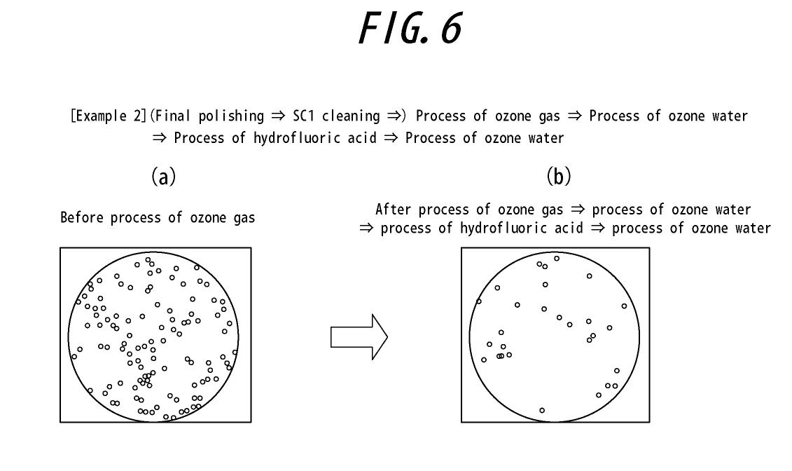

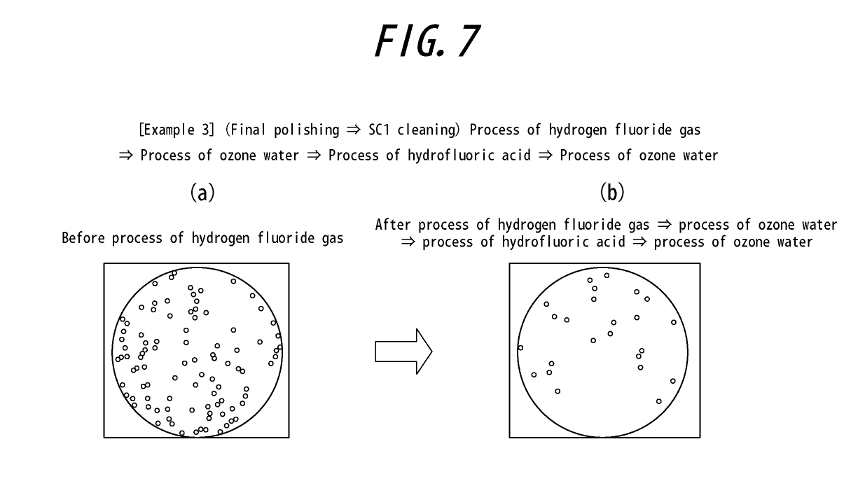

FIG. 4(a) to FIG. 4(c) show the measurement results of Example 1. FIG. 4(a) indicates the distribution of and the number of LPD on the wafer surface before the SC1 cleaning process; FIG. 4(b) indicates those after the process of hydrogen fluoride gas of (2) above; and, FIG. 4(c) indicates those after the process of ozone water of (5) above. FIG. 5(a) and FIG. 5(b) show the measurement results of Comparative Example 1. FIG. 5(a) indicates the distribution of and the number of LPD on the wafer surface before the process of ozone water of (3) above; and, FIG. 5(b) indicates those after the process of ozone water of (5) above. FIG. 6(a) and FIG. 6(b) show the measurement results of Example 2. FIG. 6(a) indicates the distribution of and the number of LPD on the wafer surface before the process of ozone gas of (1) above; and, FIG. 6(b) indicates those after the process of ozone water of (5) above. FIG. 7(a) and FIG. 7(b) show the measurement results of Example 3. FIG. 7(a) indicates the distribution of and the number of LPD on the wafer surface before the process of hydrogen fluoride gas of (2) above; and, FIG. 7(b) indicates those after the process of ozone water of (5) above.

With Comparative Example 1, which only employs the wet treatment of the diffusion controlled process, the level of LPD defects cannot be sufficiently suppressed as illustrated in FIG. 5(b). On the other hand, with Example 1, which is subjected to the surface treatment having two steps of reaction controlled processes prior to the diffusion controlled process, the LPD defects are suppressed to the lowest level of all the examples as illustrated in FIG. 4(c). The reason for the increase in the level of the LPD defects in FIG. 4(b) as compared with the level of the LPD defects in FIG. 4(a) is considered to be that: the LPDs are not removed in the step after the process of ozone gas and the process of hydrogen fluoride gas although the wafer surface is made uniform in this step; and, the LPDs remaining on the surface layer of the wafer are decomposed through the process of ozone gas and the process of hydrogen fluoride gas, and the number of detected LPDs increases, whereby the level of the LPD defects becomes great.

Further, with the silicon wafers of Example 2 and Example 3, which are subjected to the surface treatment including one step of reaction controlled process prior to the diffusion controlled step, the LPD defects are suppressed to be a relatively lower level as illustrated in FIG. 6(b) and FIG. 7(b) although the level is not small as compared with that obtained from Example 1, which includes two steps of reaction controlled processes.

### INDUSTRIAL APPLICABILITY

Provided is a wafer exhibiting excellent surface properties, in which variation in reaction, which has been concerned in the surface treatment with the diffusion controlled process such as conventional wet treatment, is effectively suppressed in a method for surface treatment of a wafer involving a chemical treatment.

### Explanation of Reference Characters

1 Rotary table

2 Gas supplying cup

3 Chamber

W Wafer

1. A method for surface treatment of a wafer involving a chemical treatment, characterized in that the chemical treatment includes a reaction controlled process, and a diffusion controlled process following the reaction controlled process.

2. The method for surface treatment of a wafer according to claim 1, wherein the reaction controlled process includes a step of a surface treatment using a single surface treatment agent and/or a step of a surface treatment using plural surface treatment agents.

3. The method for surface treatment of a wafer according to claim 1, wherein the reaction controlled process is a vapor-phase reaction process.

4. The method for surface treatment of a wafer according to claim 3, wherein the vapor-phase reaction process is an oxidation process.

5. The method for surface treatment of a wafer according to claim 3, wherein the vapor-phase reaction process is a reduction process.

6. The method for surface treatment of a wafer according to claim 3, wherein the vapor-phase reaction process is an oxidation process and a reduction process following the oxidation process.

7. The method for surface treatment of a wafer according to claim 1, wherein the diffusion controlled process is a liquid-phase reaction process.

8. A method for cleaning a surface of a silicon wafer, wherein the method for surface treatment of a wafer according to any one of claims 1 to 7 is employed.
